(19) United States
(12) Patent Application Publication
(10) Pub. No.: US 2015/0344298 A1
(43) Pub. Date: Dec. 3, 2015

(54) ELECTRONIC COMPONENT AND MANUFACTURING METHOD OF THE SAME

(71) Applicant: KABUSHIKI KAISHA TOSHIBA, Tokyo (JP)

(72) Inventors: Yoshiaki SHIMOOKA, Sagamihara Kanagawa (JP); Yoshiaki SUGIZAKI, Fujisawa Kanagawa (JP)

(73) Assignee: KABUSHIKI KAISHA TOSHIBA, Tokyo (JP)

(21) Appl. No.: 14/643,750

(22) Filed: Mar. 10, 2015

(30) Foreign Application Priority Data
May 30, 2014 (JP) 2014-112139

(51) Int. Cl. B81C 1/00; B81B 7/00

(52) U.S. Cl. CPC B81C 1/00285; B81B 7/0038; B81C 2203/0154

(57) ABSTRACT

According to one embodiment, an electronic component with a MEMS device includes an insulating layer on a substrate, a MEMS device including a mechanically movable part and disposed on a part of the insulating layer, a first cap layer disposed on the MEMS device on the insulating layer to form a cavity to accommodate the MEMS device in conjunction with the insulating layer, with which a plurality of through-holes are provided to connect with the cavity, and a second cap layer disposed to cover the first cap layer, wherein a groove is provided in an area surrounding the cavity from outside to pass through at least the second cap layer.

### CROSS-REFERENCE TO RELATED APPLICATIONS

This application is based upon and claims the benefit of priority from Japanese Patent Application No. 2014-112139, filed May 30, 2014, the entire contents of which are incorporated herein by reference.

### FIELD

Embodiments described herein relate generally to an electronic component including MEMS device and a manufacturing method of the same.

### BACKGROUND

Micro-electromechanical systems (MEMS) devices include mechanically movable parts, and such mechanically movable parts must be disposed within a hollow structure. To achieve this feature, a thin-film encapsulation structure is adopted in the MEMS devices.

However, in such a thin-film encapsulation structure for MEMS devices, an insulating layer may crack in its forming process. Through such an encapsulation crack, moisture from the outside enters the encapsulation and causes performance degradation in the device.

### BRIEF DESCRIPTION OF THE DRAWINGS

FIG. 1 is a cross-sectional view which shows a schematic structure of an electronic component of a first embodiment.

FIG. 2 is a cross-sectional view which shows the structure of the functional device part used in the electronic component of FIG. 1.

FIGS. 3A to 3K are cross-sectional views which show a manufacturing method of the electronic component of the first embodiment.

FIGS. 4A to 4C are cross-sectional views which show ring-shaped groove structures of an electronic component of a second embodiment.

FIGS. 5A and 5B are cross-sectional views which show ring-shaped groove structures of the electronic component of the second embodiment.

FIGS. 6A and 6B are cross-sectional views which show ring-shaped groove structures of the electronic component of the second embodiment.

FIGS. 7A to 7C are cross-sectional views which show ring-shaped groove structures of the electronic component of the second embodiment.

FIGS. 8A to 8C are cross-sectional views which show ring-shaped groove structures of the electronic component of the second embodiment.

FIGS. 9A and 9B are cross-sectional views which show ring-shaped groove structures of the electronic component of the second embodiment.

FIGS. 10A and 10B are plane view and cross-sectional view, respectively, both of which show a schematic structure of an electronic component of a third embodiment.

FIGS. 11A and 11B are plane view and cross-sectional view, respectively, both of which show a schematic structure of the electronic component of the third embodiment.

FIGS. 12A and 12B are cross-sectional views which show main structures of an electronic component of a fourth embodiment.

FIG. 13 is a plane view which illustrates a variation.

FIG. 14 is a plane view which illustrates another variation.

### DETAILED DESCRIPTION

In general, according to one embodiment, an electronic component with a MEMS device includes: an insulating layer on a substrate; a MEMS device including a mechanically movable part and disposed on a part of the insulating layer; a first cap layer disposed on the MEMS device on the insulating layer to form a cavity to accommodate the MEMS device in conjunction with the insulating layer, with which a plurality of through-holes are provided to connect with the cavity; and a second cap layer disposed to cover the first cap layer; wherein a groove is provided in an area surrounding the cavity from outside to pass through at least the second cap layer.

MEMS devices of the embodiments are, unlike other ordinary semiconductor devices, include mechanically movable parts. Thus, in the implementation of the MEMS devices, the implementation/packaging technique with a hollow structure (cavity) is essential to make use of the mechanically movable parts.

On the other hand, for better microstructure formation, cost reduction, and easy handling, an implementation technique to form a hollow structure in a wafer state instead of forming it as an individual chip is demanded. This technique is referred to as a wafer level package (WLP), and a hollow structure formed by an insulating thin film is particularly referred to as a thin-film encapsulation structure.

Hereinafter, the electronic component of the embodiments is explained with reference to accompanying drawings.

### First Embodiment

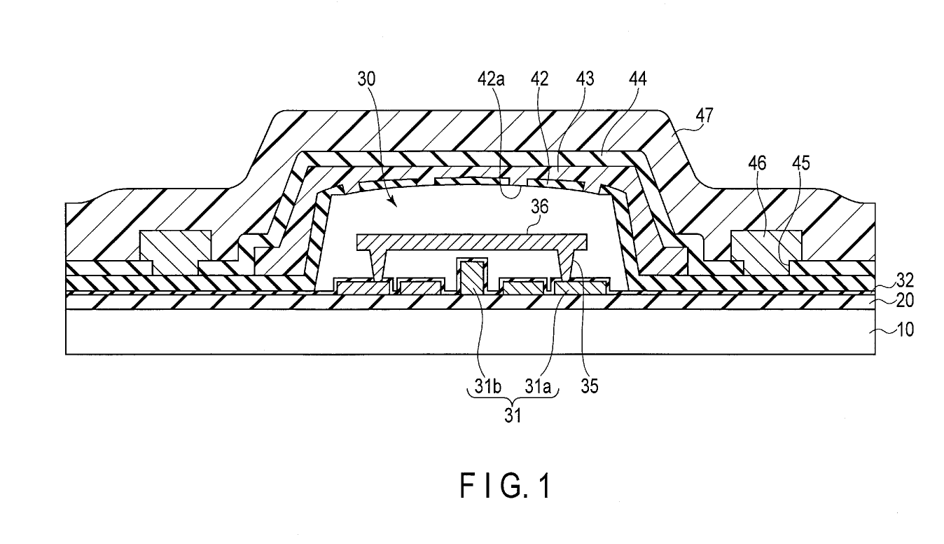

FIG. 1 is a cross-sectional view which illustrates a schematic structure of an electronic component of a first embodiment.

An insulating layer 20 having a thickness of 10 to 40 pm is disposed on a substrate 10 including a functional device (not shown) such as a CMOS circuit formed on a surface of a semiconductor substrate of Si or the like.

A lower electrode 31 of a MEMS device 30 is disposed at a part of the insulating layer 20. The lower electrode 31 is composed of an electrode 31a with which an anchor (described later) is provided and an electrode 31b which can come close to an upper electrode (described later).

A passivation film 32 formed of a thin insulating layer is disposed on the insulating layer 20 to cover the lower electrode 31. The passivation film 32 is partly removed over the electrode 31a. Through the part where the passivation film 32 is partly removed, a lower end (one end) of the anchor 35 is connected to the electrode 31a. The upper electrode 36 of the MEMS device is disposed to be connected to an upper end (the other end) of the anchor 35. The upper electrode 36 is movable except the part connected to the anchor 35, and constitutes a variable capacitor in conjunction with the electrode 31b.

A first cap layer 42 is disposed on the passivation film 32 to form a cavity (thin-film encapsulation) in which the MEMS device 30 including the lower electrode 31, anchor 35, and upper electrode 36 are accommodated. The first cap layer 42 is a silicon compound mainly containing, for example, an Si—O coupling of an inorganic material, that is, a silicon oxide film having a thickness of 1 μm.

A plurality of through-holes 42a are pierced through the first cap layer 42 to reach inside the thin-film encapsulation. The through-holes 42a are used to remove a sacrificial layer (described later) therethrough by, for example, aching for forming the thin-film encapsulation.

A sealing film 43 formed of organic resin such as polyimide is disposed on the cap layer 42 to cover the through-holes 42a. The sealing film 43 is formed of, for example, UV-cured resin whose main component is carbon. Specifically, it is a resin film containing, for example, prepolymer, monomer, photopolymerization starter, and additive. Here, the sealing film 43 may be formed to seal the through-holes 42a securely, and for this reason, it is formed to cover a range slightly over the thin-film encapsulation.

A second cap layer 44 is disposed on the first cap layer 42 to cover the sealing film 43, and the second cap layer 44 is a silicon compound whose main component is, for example, an Si—N coupling of an inorganic material, that is, a silicon nitride (SiN) film. The second cap layer 44 has a gas permeability less than that of the first cap layer 42, which means it is superior in the moisture-proof point. Thus, the second cap layer 44 functions as a film to prevent a harmful gas such as moisture from permeating through the sealing film 43 into the encapsulation. As the second cap layer 44, a silicon carbide (SiC) film, aluminum oxide (Sl₂O₃) film, and aluminum nitride (AlN) film can be used instead of SiN.

A through-hole (groove) 45 is disposed to surround the thin-film encapsulation from outside piercing through the second cap layer 44. That is, a ring-shaped groove 45 is disposed on the pattern around the thin-film encapsulation. In the groove 45, a metal film 46 such as Cu is embedded.

Furthermore, a protective film 47 formed of organic material resin is disposed to cover the second cap layer 44 and the metal film 46. The protective film 47 is formed of an insulative material which is more flexible than the second cap layer 44 and effective for preventing moisture from entering the thin-film encapsulation.

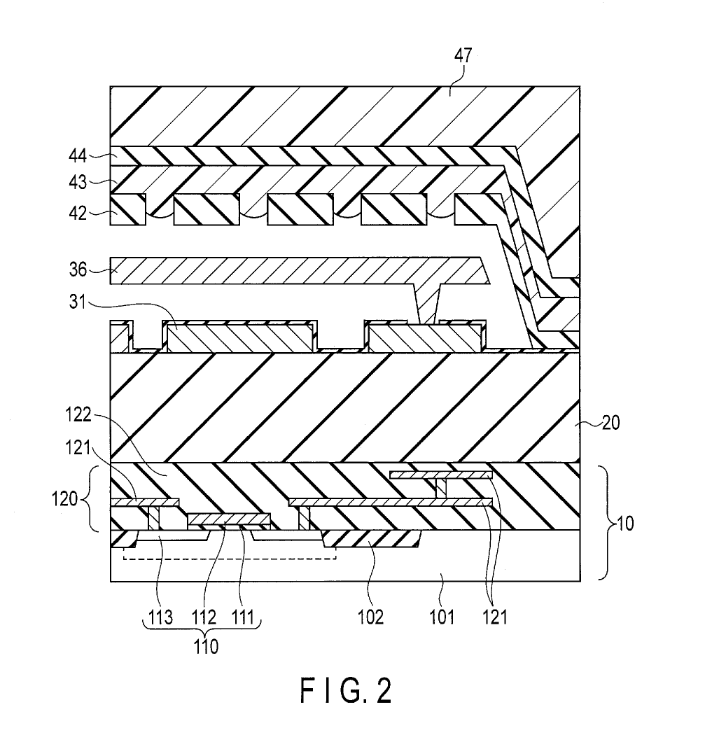

FIG. 2 is a cross-sectional view which illustrates an example of a CMOS circuit formed on the substrate 10. On a surface of a semiconductor substrate 101 formed of Si or the like, a MOS transistor 110 composed of a gate insulating film 111, gate electrode 112, and source/drain region 113 is formed. Note that, although only a single transistor is shown in FIG. 2, the CMOS circuit is actually structured with a plurality of transistors. On the transistor 110, a multilayered wiring 120 including an interlayer insulating film 122 formed of SiO₂ or the like and a wire layer 121 formed of Al or the like is disposed. Then, the insulating layer 20 which is relatively thick is disposed on the multilayered wiring 120 and the MEMS device is formed on the insulating layer 20.

Here, the multilayered wiring 120 including the transistor 110 has a film thickness of approximately 5 μm and the insulating layer 20 has a film thickness of 10 to 40 μm which is relatively thicker. Furthermore, the MEMS part has a film thickness of approximately 30 μm. Although this is not depicted in the Figure, the MEMS device and the CMOS circuit are electrically connected to each other through a via formed in the insulating layer 20.

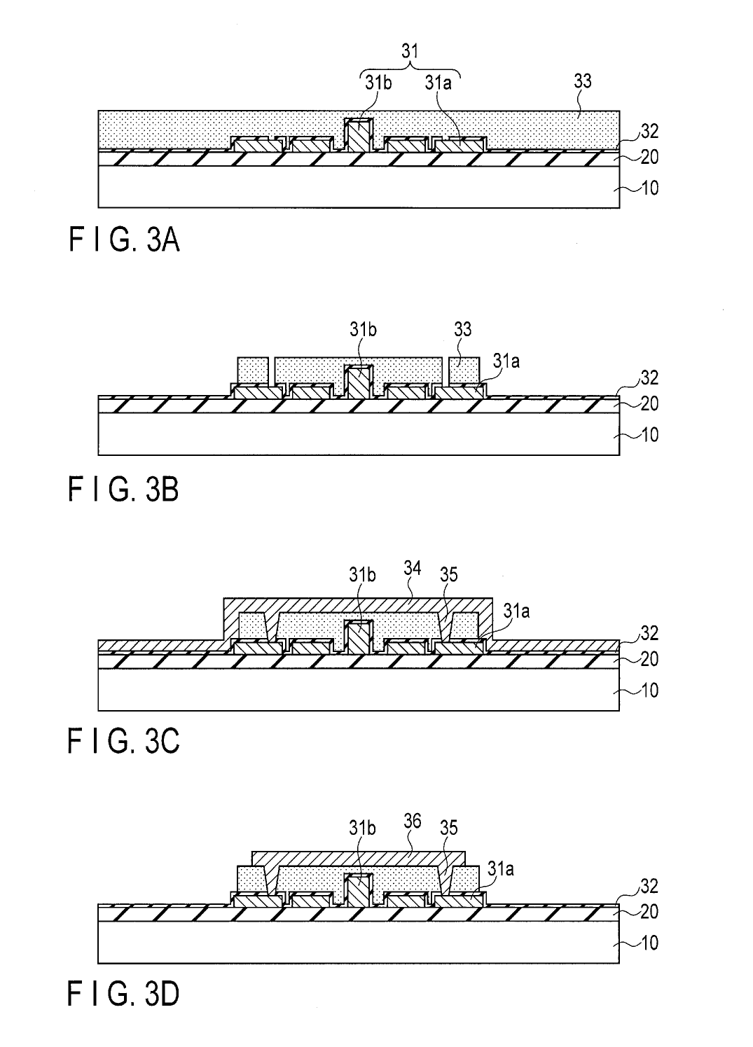

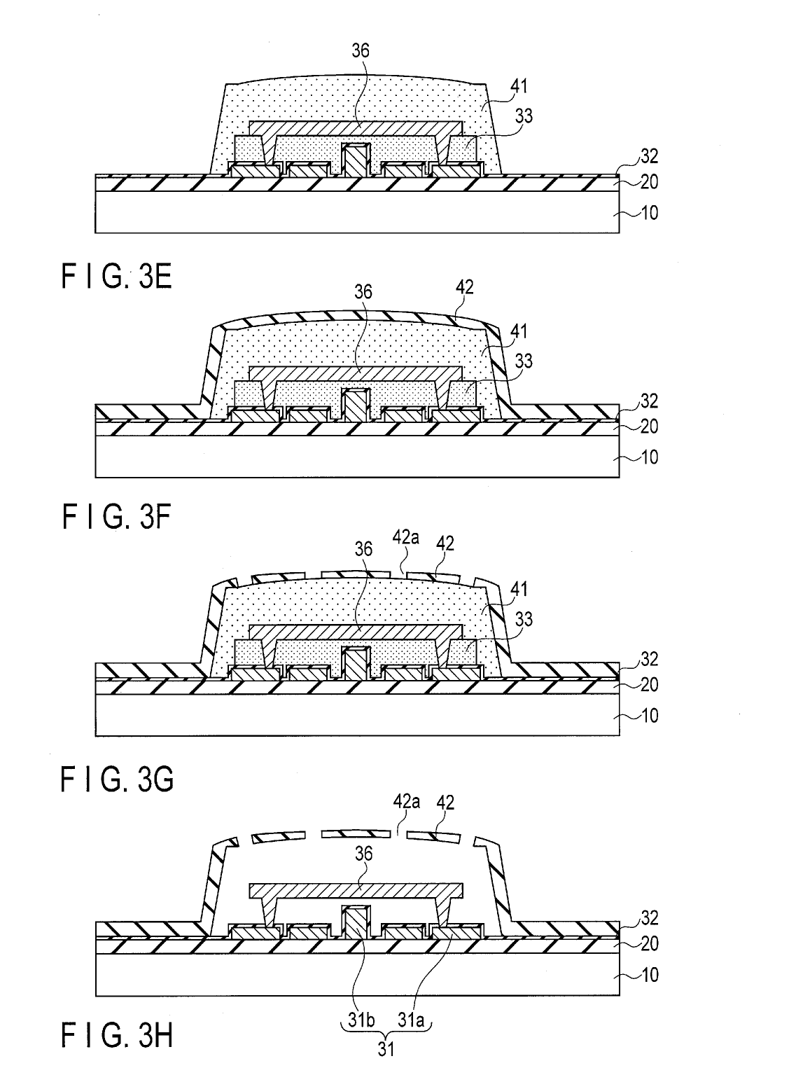

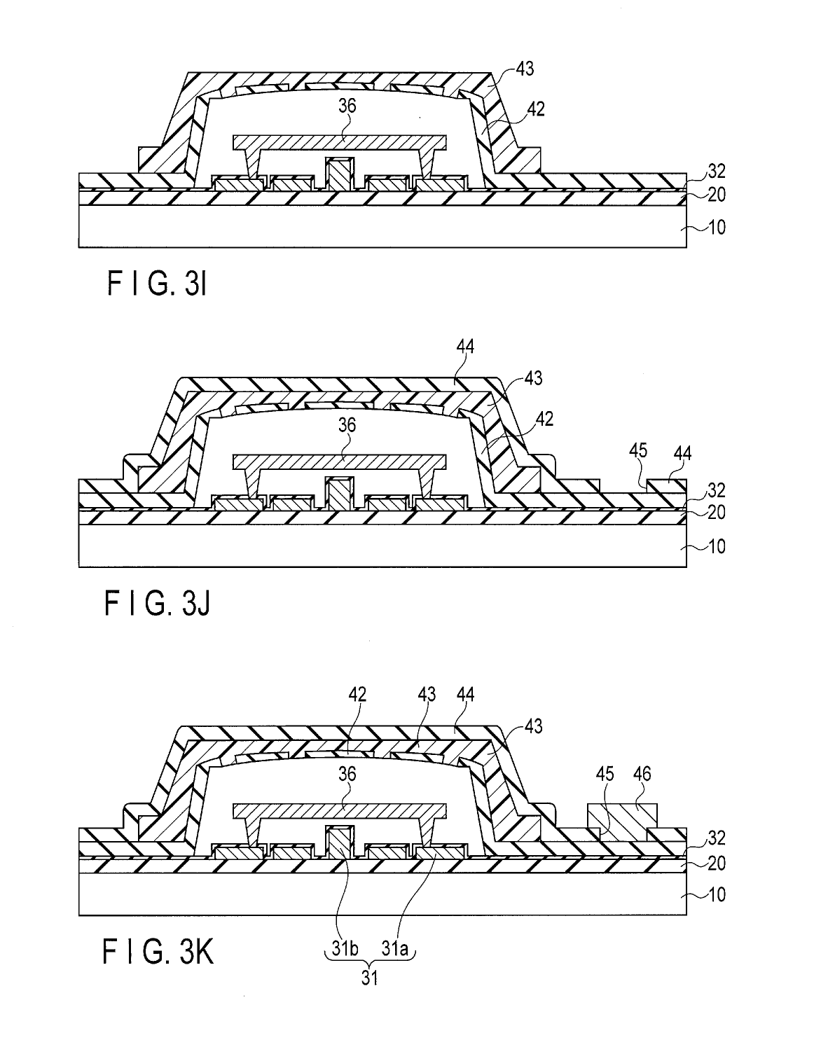

Next, a manufacturing method of the electronic component of the embodiments is explained with reference to FIGS. 3A to 3K.

First, as shown in FIG. 3A, an insulating layer 20 formed of SiO or the like is formed on the substrate 10 and a lower electrode 31 (31a and 31b) formed of Al or the like is formed thereon. The insulating layer 20 has a thickness of 30 μm and the lower electrode 31 has a thickness of a few hundred nanometers to a few micrometers. A passivation film 32 formed of SiO, SiN, and the like is formed, by a chemical vapor deposition (CVD) method and the like, on the insulating layer 20 to cover the lower electrode 31. The passivation film has a thickness of a few dozen to a few hundred nanometers. Furthermore, on the electrode 31a, part of the passivation film 32 is opened to form a hole to pass an anchor therethrough. Then, a first sacrificial layer 33 formed of an organic material such as polyimide is disposed.

Note that, as described above, the substrate 10 includes a CMOS circuit and the like formed on the semiconductor substrate 101, and the CMOS circuit is electrically connected to a MEMS device which is formed later.

Next, as shown in FIG. 3B, a first sacrificial layer 33 is patterned into a desired shape. Note that the sacrificial layer 33 may be patterned by a photosensitive exposure/development method performed after the application of the sacrificial layer 33 having a thickness of a few hundred nanometers to a few micrometers. Or, the sacrificial layer 33 may be patterned by forming a resist pattern thereon by an ordinary lithography method and then selectively etching the resist pattern by a reactive ion etching (RIE) method. Or, the sacrificial layer 33 may be patterned by forming an SiO film or the like formed thereon, patterning the SiO film using a resist pattern formed by an ordinary lithography method and an RIE method or a wet etching method, and then etching the pattern using the patterned SiO film as a hard mask.

Furthermore, a hole corresponding to the hole pierced through the passivation film 32 is opened on the sacrificial layer 33. Note that the hole pierced through the passivation film 32 to connect the electrode 31a may not necessarily be provided in advance and it may be opened at the same time when the hole on the first sacrificial layer 33 is opened.

Then, as shown in FIG. 3C, a metal film 34 formed of Al or the like is formed to cover the entire surface by sputtering and the like. The metal film 34 has a thickness of a few hundred nanometers to a few micrometers.

Then, as shown in FIG. 3D, the metal film 34 is patterned to be a line as an upper electrode 36 of MEMS. Here, part of the metal film 34, that is, the part filling the hole pierced through the sacrificial layer 33 and contacting the electrode 31a becomes the anchor 35. The metal film 34 may be patterned by a resist pattern formed by ordinary lithography and RIE or may be patterned by wet etching.

Then, as shown in FIG. 3E, a thin-film encapsulation formation process is started. A second sacrificial layer 41 formed of an organic material such as polyimide is applied and patterned to reside on a part to be a encapsulation space. Note that the sacrificial layer 41 may be patterned by a photosensitive exposure/development method performed after the application of the sacrificial layer 41 having a thickness of a few hundred nanometers to a few micrometers. Or, the sacrificial layer 41 may be patterned by forming a resist pattern thereon by an ordinary lithography method and then selectively etching the resist pattern by RIE method. Or, the sacrificial layer 41 may be patterned by forming an SiO film or the like formed thereon, patterning the SiO film using a resist pattern formed by an ordinary lithography method and an RIE method or a wet etching method, and then etching the pattern using the patterned SIC film as a hard mask.

Next, as shown in FIG. 3F, a first cap layer 42 formed of an inorganic material such as SiO is formed on the second sacrificial layer 41 and passivation film 32 by CVD or the like. The first cap layer 42 is formed to be a thin-film encapsulation layer and has a thickness of a few hundred nanometers to a few micrometers.

Then, a resist (not shown) is applied on the cap layer 42 and photosensitive patterning is performed using ordinary lithography. After that, as shown in FIG. 3G, through-holes 42a for removing sacrificial layer are formed on the cap layer 42 using RIE or wet etching.

Next, as shown in FIG. 3H, the resist pattern for through-holes (not shown), first sacrificial layer 33, and second sacrificial layer 41 are removed by ashing with O₂ gas or the like in order to form a thin-film encapsulation. After this step, the upper electrode 36 of MEMS 30 is movable. Here, the sacrificial layers 33 and 41 within the thin-film encapsulation can easily be removed through the through-holes 42a by ashing.

Next, as shown in FIG. 3I, a sealing layer 43 formed of an organic material such as polyimide or the like is formed to seal the through-holes 42a in the first cap layer 42. Then, the sealing layer 43 is patterned in a desired shape. Note that the sacrificial layer 43 may be patterned by a photosensitive exposure/development method performed after the application of the sacrificial layer 43 having a thickness of a few hundred nanometers to a few micrometers. Or, the sacrificial layer 43 may be patterned by forming a resist pattern thereon by an ordinary lithography method and then selectively etching the resist pattern by RIE method. Or, the sacrificial layer 43 may be patterned by forming an SiO film or the like formed thereon, patterning the SiO film using a resist pattern formed by an ordinary lithography method and an RIE method or a wet etching method, and then etching the pattern using the patterned SiO film as a hard mask.

Next, as shown in FIG. 3J, a second cap layer 44 which is an insulating film formed of an inorganic material such as SiN or the like is formed as a moisture-proof layer. The second cap layer 44 is formed by CVD or the like to have a thickness of a few hundred nanometers to a few micrometers. Then, a pattern forming for electrode opening and the like is performed by ordinary lithography and RIE or wet etching to finish the thin-film encapsulation structure formation. At the same time, at least one groove 45 formed as a ring-shaped pattern surrounding the thin-film encapsulation is prepared on the field (in the Figure, only one of the two cross-sections of the ring pattern is shown). More specifically, a resist mask having a ring-shaped opening surrounding the thin-film encapsulation is formed on the second cap layer 44 which is selectively etched by RIE.

Here, the ring-shaped groove 45 needs to pierce through at least the second cap layer 44. That is, the groove 45 may pass through the second cap layer 44 alone or may reach the first cap layer 42. Furthermore, the groove 45 may pass through the first and second cap layers 42 and 44 and halfway through the insulating layer 20 between the CMOS circuit and the MEMS device.

Next, as shown in FIG. 3K, the ring-shaped groove 45 is filled with a metal film 46 formed of Cu or the like using, for example, Cu rewiring. Specifically, a barrier metal layer formed of Ti or TiN whose thickness is a few dozen to a few hundred nanometers and a Cu seed layer are formed by sputtering. Then, a desired pattern is formed in the resist film using ordinary lithography and Cu is embedded in the pattern by electrolytic plating or the like. After the resist film is peeled off, the barrier metal layer and Cu seed layer are wet etched, and the ring-shaped pattern of the groove 45 surrounding the thin-film encapsulation in which Cu metal film 46 is embedded is furnished.

Note that, since moisture easily enters the second cap layer 44 which is formed of SiN or the like, the end portion thereof should preferably be unexposed by the etching process. The metal film 46 embedded inside the groove 45 works effectively for preventing the moisture entrance from the end portion of the second cap layer 44. Note that, if such a moisture entrance is not a problem, the metal film 46 is not necessarily embedded. In that case, the ring-shaped pattern surrounding the thin-film encapsulation is structured only as the groove 45 formed in the second cap layer 44.

Thereinafter, a protective film 47 formed of, for example, an organic passivation resin is prepared and patterned on the device for its protection sake and the structure shown in FIG. 1 is made.

As can be understood from the above, in the present embodiment, the device is structured such that the ring pattern groove is disposed in the field surrounding the thin-film encapsulation for accommodating the MEMS device 30. More specifically, the groove 45 passing through the second cap layer 44 is disposed in the ring-shaped region around the thin-film encapsulation. Thus, even if cracks are made on the thin-film encapsulation, they can be prevented from entering inside the thin-film encapsulation. Furthermore, even if cracks are made inside the thin-film encapsulation, they can be prevented from propagating through the field to cause other cracks in thin-film encapsulations of other adjacent MEMS devices. That is, the number of no good devices due to encapsulation cracks can be reduced. Consequently, a WLP technique which forms a hollow structure showing high reliability in a wafer state can be achieved.

Note that, among the insulating layer 20, first cap layer 42, and second cap layer 44 in the thin-film encapsulation, the second cap layer 44 is hardest and easily propagate cracks. Thus, the groove 45 formed passing through the second cap layer 44 is effective for preventing cracks propagating through the second cap layer 44 having such a weakness. Moreover, the groove 45 formed passing through the first cap layer 42, and formed reaching the inside of the insulating layer 20 are more effective for preventing the propagation of cracks.

Furthermore, the groove 45 may be formed passing through the insulating layer 20. Note that the groove 45 formed not passing through the insulating layer 20 does not require a deeply grooved part, and thus can be formed relatively easily without making serious damage to the lower layer of the device.

### Second Embodiment

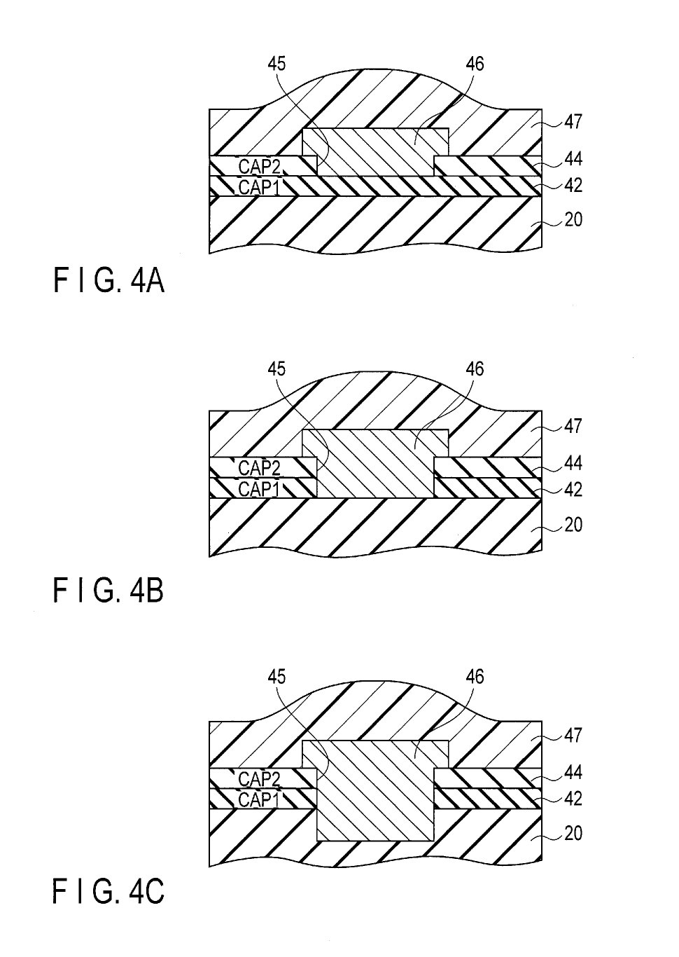

FIGS. 4A, 4B, and 4C to 9A and 9B are to explain electronic component of the second embodiment, and are cross-sectional views which show a ring-shaped pattern disposed around a thin-film encapsulation of a MEMS device. The parts equivalent to those shown in FIG. 1 are referred to by the same reference numbers and their detailed explanations are omitted.

The position of ends of first and second cap layers 42 and 44 and the depth of a groove are varied in various ways.

Specifically, FIG. 4A is an example showing a through-hole 45 formed in the second cap layer 44 alone. FIG. 4B is an example showing the through-hole 45 formed in both the first and second cap layers 42 and 44. FIG. 4C is an example showing a groove 45 passing through the first and second cap layers 42 and 44 and halfway through the insulating layer 20.

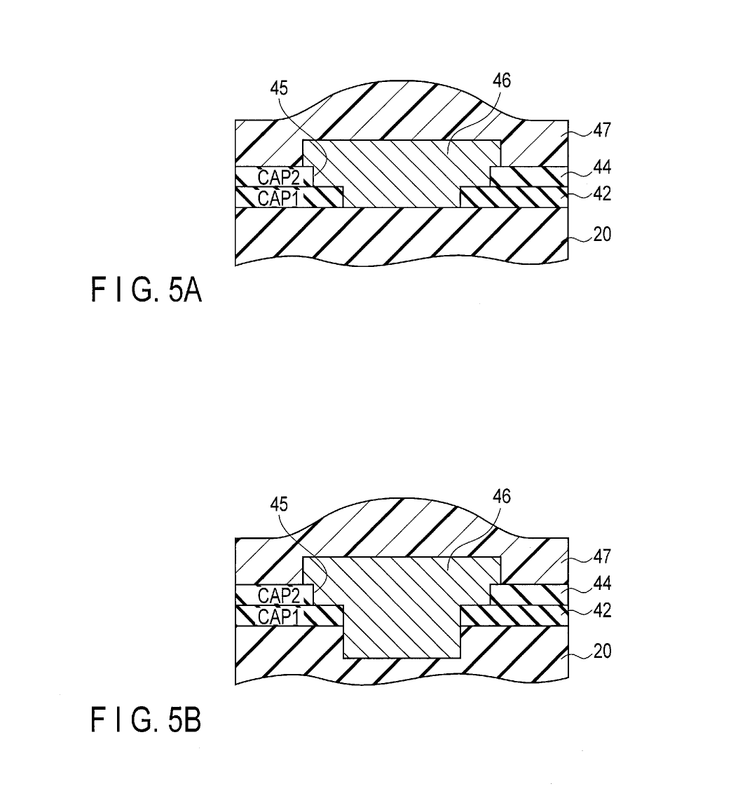

FIG. 5A is an example showing the second cap layer 44 recessed and the through-hole 45 formed in the first cap layer 42. FIG. 5B is an example showing the second cap layer 44 recessed and the groove 45 formed passing through the first cap layer 42 and halfway through the insulating layer 20.

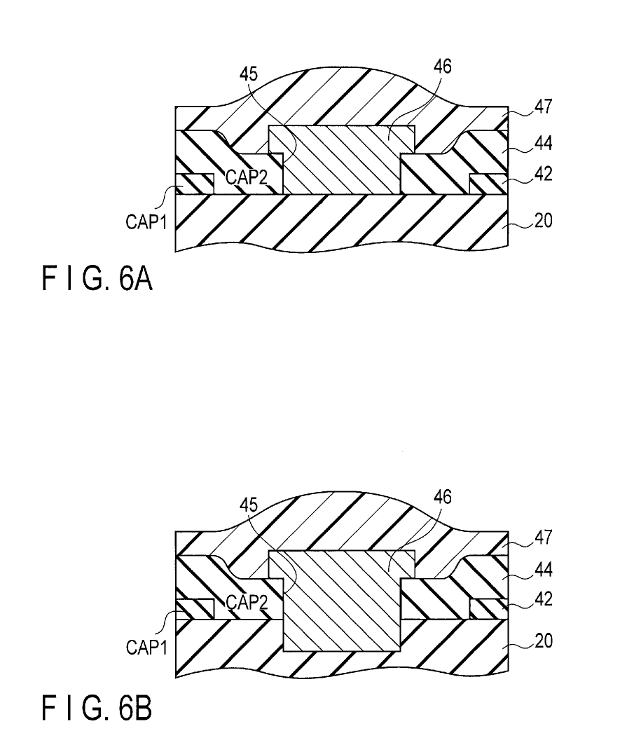

FIG. 6A is an example showing the first cap layer 42 recessed and the through-hole 45 is formed in the second cap layer 44. FIG. 6B is an example showing the first cap layer 42 recessed and the groove 45 passing through the second cap layer 44 and halfway through the insulating layer 20.

Note that, in the above examples, a metal film 46 of Cu or the like is formed to fill the groove (through-hole) 45 and a protective film 47 of organic resin or the like is formed thereon.

As can be understood from the above, the ring pattern can be modified in various ways and, the propagation of encapsulation cracks inside/outside the encapsulation can be prevented in any modification. Furthermore, the metal film 46 embedded in the groove 45 is effective for preventing the moisture entrance from the end portion of the second cap layer 44. Note that, if such a moisture entrance is not a problem, the metal film 46 is not necessarily embedded. Furthermore, if the cap layers 42 and 44, the sealing film 43, and the like can provide a sufficient protection, the protective film 47 can be omitted.

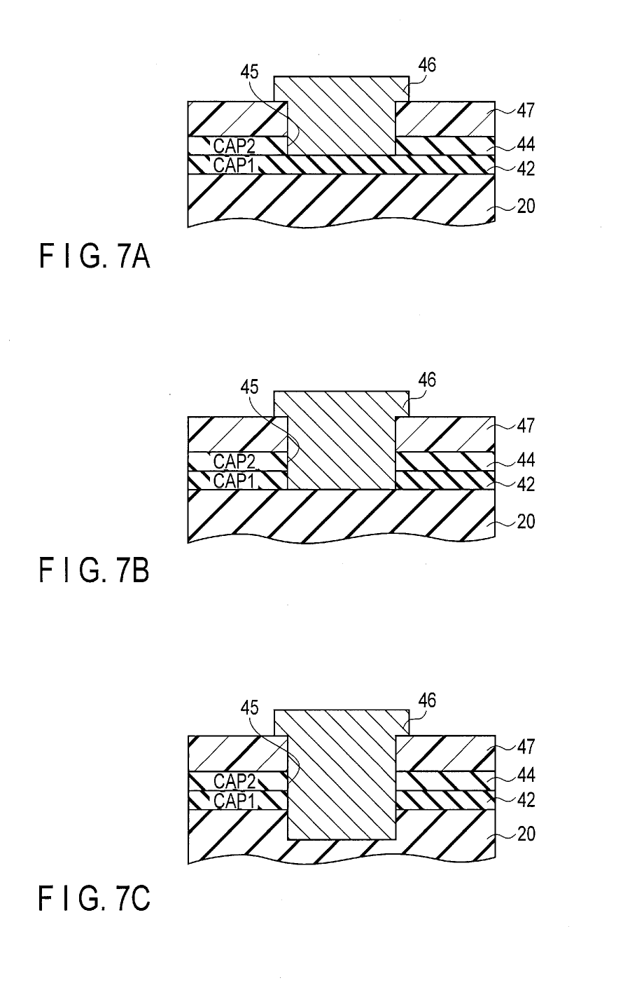

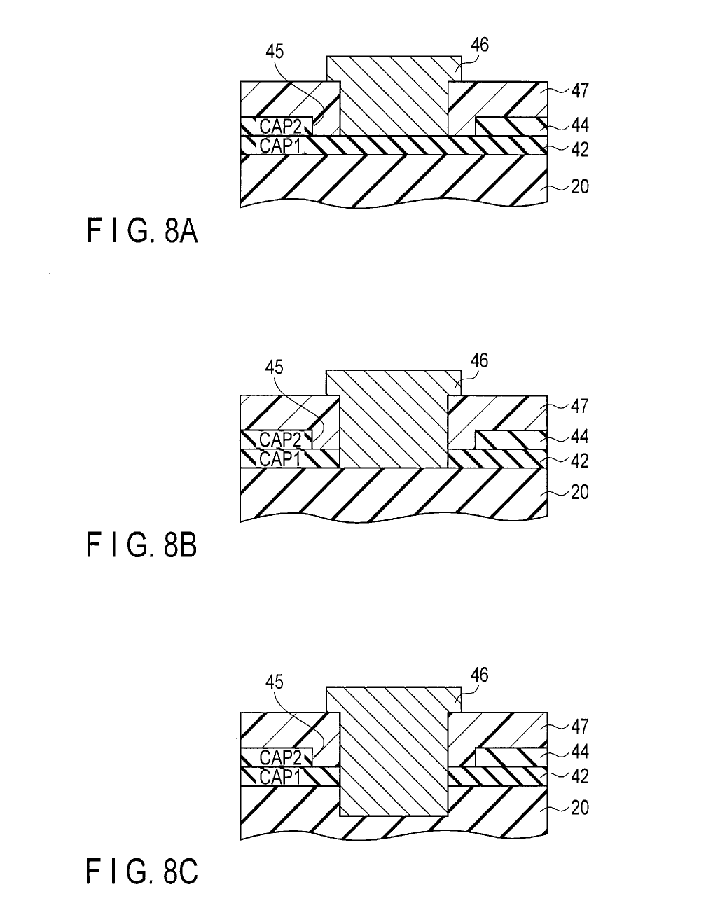

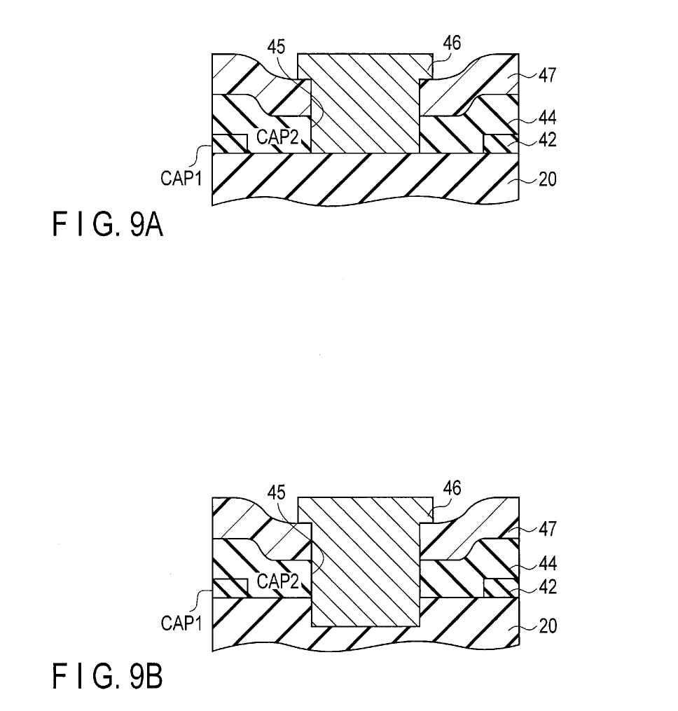

FIGS. 7A, 7B, and 7C to FIGS. 9A and 9B are examples in which the formation order of the through-hole (groove) 45 and the protection film 47 is switched. FIGS. 7A, 7B, and 7C correspond to FIGS. 4A, 4B, and 4C. FIGS. 8A, 8B, and 8C correspond to FIGS. 5A and 5B. FIGS. 9A and 9B correspond to FIGS. 6A and 6B.

Specifically, FIG. 7A is an example showing the through-hole 45 formed in the protective film 47 and the second cap layer 44. FIG. 7B is an example showing the through-hole 45 formed in the protective film 47 and the first and second cap layers 42 and 44. FIG. 7C is an example showing the groove 45 passing through the protective film 47 and the first and second cap layers 42 and 44 and halfway through the insulating layer 20.

FIG. 8A is an example showing the second cap layer 44 recessed and the groove 45 formed in the protective film 47. FIG. 8B is an example showing the second cap layer 44 recessed and the through-hole 45 formed passing through the protective film 47 and the first cap layer 42. FIG. 8C is an example showing the second cap layer 44 recessed and the groove 45 passing through the protective film 47 and the first cap layer 42 and halfway through the insulating layer 20.

FIG. 9A is an example showing the first cap layer 42 recessed and the through-hole 45 formed in the protective film 47 and the second cap layer 44. FIG. 9B is an example showing the first cap layer 42 recessed and the groove 45 passing through the second cap layer 44 and halfway through the insulating layer 20. In that case, the metal film 46 may be omitted likewise.

As can be understood from the above, in the present embodiment, the groove 45 which is a ring shape pattern if formed outside the thin-film encapsulation for containing the MEMS device 30, and the same advantage explained in the first embodiment can be achieved. Here, since the structure and the depth of the groove 45 can be modified arbitrarily, any suitable mode which can effectively reduce the propagation of cracks inside/outside the thin-film encapsulation should be chosen.

### Third Embodiment

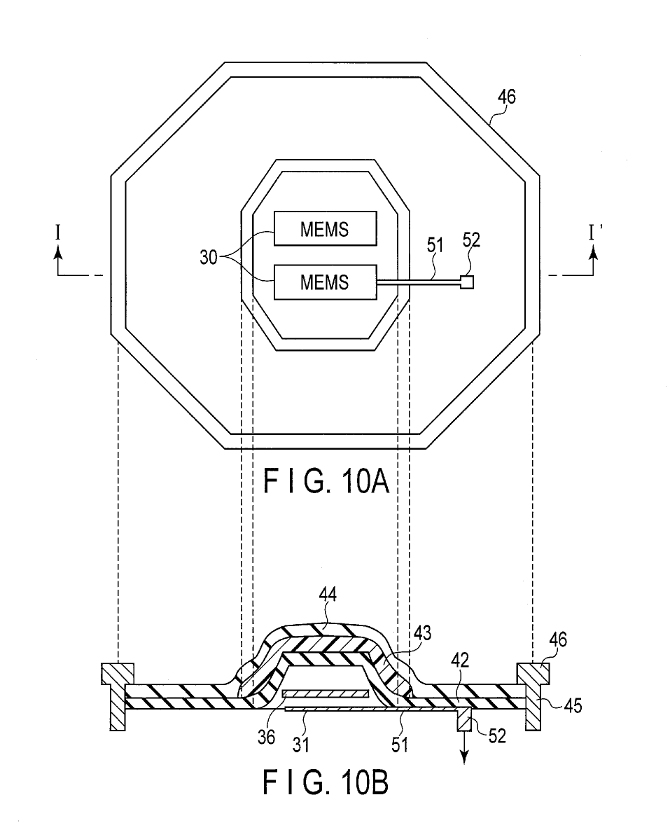

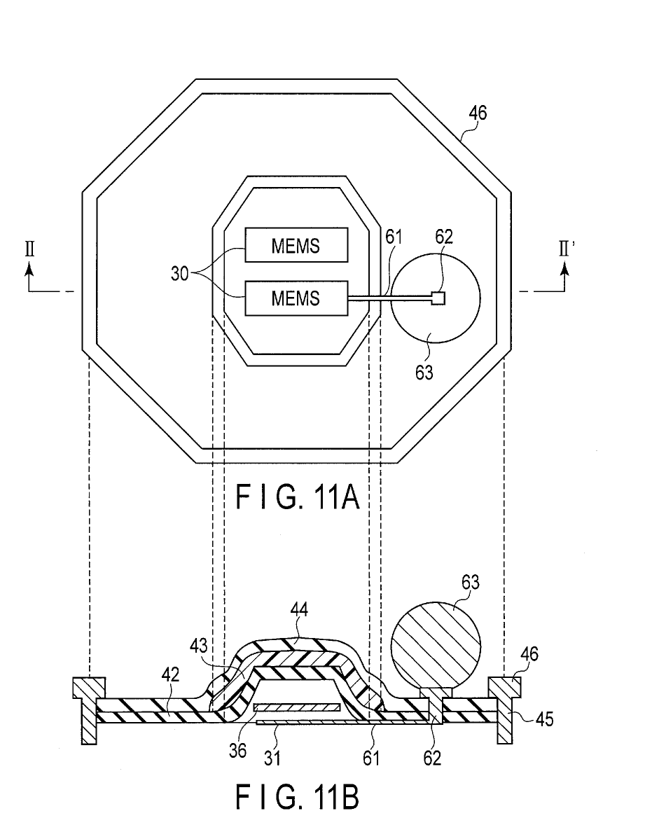

FIGS. 10A and 10B, and 11A and 11B are to explain an electronic component of the third embodiment, and show examples of how an leading line from the MEMS device is arranged. FIGS. 10A and 11A are plane views. FIG. 10B is a cross-sectional view taken along line I-I′ in FIG. 10A. FIG. 11B is a cross-sectional view taken along line II-II′ in FIG. 11B. Note that the parts equivalent to those shown in FIG. 1 are referred to by the same reference numbers and their detailed explanations are omitted.

FIGS. 10A and 10B show an example in which an leading line 51 drawn from the MEMS device 30 goes downward inside the ring-shaped pattern, that is, goes to the CMOS circuit side. In this case, a via 52 passing through the insulating layer 20 is formed.

On the other hand, FIGS. 11A and 11B show an example in which an leading line 61 drawn from the MEMS device 30 goes upward inside the ring-shaped pattern, that is, goes to the outside of the device. In this case, a via 62 passing through the first and second cap layers 42 and 44 is formed, and am external terminal 63 such as a bump or a pad is formed on the upper surface side of the via 62.

Note that, in the above examples, the ring-shaped pattern is formed to surround a plurality of MEMS devices 30; however, as a matter of course, the pattern can be formed to surround only a single MEMS device 30. Furthermore, in the above examples, a metal film 46 is embedded in the groove 45 of the ring-shaped pattern; however, the metal film 46 can be omitted.

As can be understood from the above, in the present embodiment, the leading line from the MEMS device 30 is drawn inside the ring-shaped pattern to maintain the advantage of reducing the crack propagation due to the ring-shaped pattern.

Moreover, the structures shown in FIGS. 10A, 10B, 11A, and 11B may be adopted at the same time. That is, the leading line 51 from the MEMS device 30 may be connected to the via 52 passing through the insulating layer 20 inside the ring-shaped pattern while the other leading line 61 from the MEMS device 30 may be connected to the via 62 passing through the first and second cap layers 42 and 44 inside the ring-shaped pattern.

### Fourth Embodiment

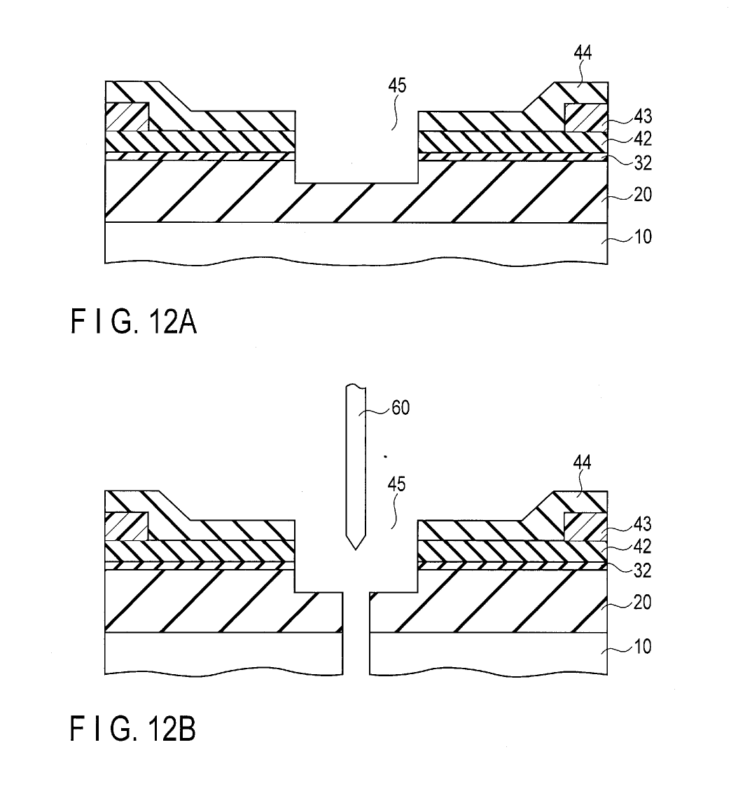

FIGS. 12A and 12B are to explain an electronic component of the fourth embodiment, and show examples in which a ring-shaped pattern is applied to a part to be diced. Note that the parts equivalent to those shown in FIG. 1 are referred to by the same reference numbers and their detailed explanations are omitted.

When a plurality of devices formed on a substrate are divided into various chips, they are divided, in general, by a dicing process using a blade. At that time, shallow grooves must be formed on the surface of the substrate for positioning of the blade.

In the present embodiment, as shown in FIG. 12A, a groove 45 is formed to pass through first and second cap layers 42 and 44 and reach an insulating layer 20. Specifically, a mask (not shown) having an aperture for a dicing line is formed on the top of the second cap layer 44, and then, a selectively etching process is performed by, for example, RIE. Through this process, the groove 45 passing through the second cap layer 44, cap layer 42, and passivation film 32 and halfway through the insulating layer 20 can be formed. Thereafter, as shown in FIG. 12B, dicing is performed at the center of the groove 45 using a blade 60 to divide the substrate into a plurality of chips.

Here, the structure inside the dicing lines, that is, the structure of each chip may be formed as in the third embodiment explained above. For example, in the structure shown in FIGS. 10A and 10B, the groove 45 may be formed along the dicing line and dicing is performed by the blade 60 without forming a metal film 46. Furthermore, the structure shown in FIGS. 11A and 11B can be modified in the same manner. Moreover, the combination of the structures shown in FIGS. 10A and 10B and 11A and 11B can be modified in the same manner.

As can be understood from the above, in the present embodiment, the groove 45 of ring-shaped pattern is formed along the dicing line for easier dicing operation. Note that, since the first and second cap layers 42 and 44 are etched by, for example, RIE, no force is applied due to the contact between the blade 60 and the cap layers 42 and 44. That is, no cracks are produced on the first and second cap layers 42 and 44 by the dicing process.

That is, if the blade 60 contacts the second cap layer 44 which is relatively hard because of its inorganic material such as SiN or the like, cracks may be produced on the second cap layer 44; however, as in the present embodiment, the groove 45 formed along the dicing line can avoid the contact between the blade 60 and the second cap layer 44, and thus, a possible cause of cracks can be removed.

Moreover, since the groove 45 is formed halfway through the insulating layer 20, a peeling-off of the insulating layer 20 does not occur. If the groove 45 is formed passing through the insulating layer 20, the thick end surface of the insulating layer 20 is exposed and a peeling-off may occur in the insulating layer 20 due to applied force. On the other hand, in this embodiment, the groove 45 is formed to stop in the middle of the insulating layer 20, and thus, such a peeling-off can be prevented in advance. Furthermore, as shown in FIG. 2, the insulating layer 20 is thick enough as compared to the multilayered wirings and the like at the lower part of the device, and thus, the etching process can easily be stopped in the middle of the insulating layer 20. Moreover, since the etching process can be stopped halfway through the insulating layer 20, damage to the lower layer of the device can be prevented.

Furthermore, by applying the structure of the present embodiment to the structure of the third embodiment, the crack propagation due to the ring-shaped pattern can be reduced advantageously as in the third embodiment.

### (Modifications)

Note that the present invention is not limited to the embodiments described above.

The functional device provided with the substrate is not necessarily a CMOS circuit and can be any circuit device. Furthermore, the number of MEMS device in the thin-film encapsulation is not limited to one or tow, and can be three or more. Moreover, the ring-shaped pattern is not necessarily formed to surround a single thin-film encapsulation and can be formed to surround a plurality of thin-film encapsulations.

The structure of the MEMS device does not necessarily include a capacitor as shown in FIG. 1 and can be designed freely as long as it includes a mechanically movable part. For example, the structure may include a switch device which controls a contact/release between upper and lower electrodes by a movement of a conductive movable part.

The sealing film is provided for sealing through-holes on the first cap layer; however, if the second cap layer securely seals the through-holes, the sealing film can be omitted. Moreover, if the cap layer alone can sufficiently protect inside the thin-film encapsulation, a protective film can be omitted.

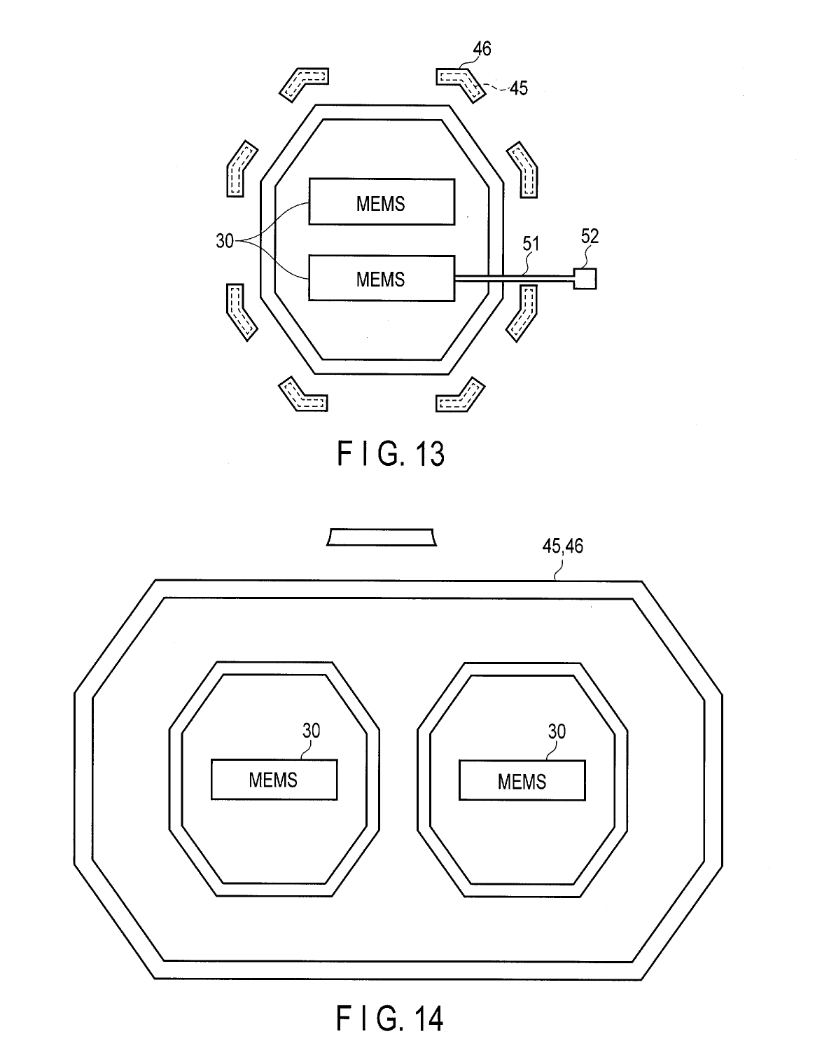

Furthermore, if the thin-film encapsulation is formed as a polygon instead of a circle, the groove surrounding the thin film encapsulation is not necessarily made continuously. For example, as shown in FIG. 13A, a groove 45 and a metal film 46 may be provided selectively to correspond to each corner of such a polygonal thin-film encapsulation along the corner. Further, the groove 45 is not necessarily limited to the structure to surround one thin-film encapsulation, but it is also possible that a groove 45 has such a structure as to surround a plurality of thin-film encapsulations, as shown in FIG. 14.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. An electronic component with a MEMS device, comprising:
an insulating layer on a substrate;
a MEMS device including a mechanically movable part, the MEMS device disposed on a part of the insulating layer;
a first cap layer disposed on the MEMS device and the insulating layer, the first cap layer forming a cavity to accommodate the MEMS device in conjunction with the insulating layer and having a plurality of through-holes thereon connecting with the cavity; and
a second cap layer disposed to cover the first cap layer, wherein
a groove is provided in an area surrounding the cavity from outside to pass through at least the second cap layer.

2. The electronic component of claim 1, wherein the groove is engraved on the upper surface of the second cap layer to a depth not passing through the insulating layer.

3. The electronic component of claim 1, further comprising a CMOS circuit disposed on the surface of the substrate.

4. The electronic component of claim 1, wherein the MEMS device comprises:
a lower electrode provided on the insulating layer;
an anchor whose one end is connected to the lower electrode; and
an upper electrode movably connected to the other end of the anchor.

5. The electronic component of claim 1, wherein a metal film is embedded in the groove.

6. The electronic component of claim 1, further comprising a sealing film to seal the through-holes on the first cap layer, the sealing film interposed between the first cap layer and the second cap layer.

7. The electronic component of claim 1, further comprising a protective film formed of an organic material on the second cap layer.

8. The electronic component of claim 7, wherein the protective film is an insulating film having a greater flexibility than the second cap layer.

9. The electronic component of claim 1, wherein the second cap layer has a gas permeability less than that of the first cap layer.

10. The electronic component of claim 1, wherein the groove is disposed along a dicing line used to separate the substrate into a plurality of chips.

11. The electronic component of claim 10, wherein the groove is engraved on the upper surface of the second cap layer to pass through the second and first cap layers and halfway through the insulating layer.

12. The electronic component of claim 1, further comprising, within the area including the groove, a leading line electrically connected to the MEMS device and a via continuing downward through the insulating layer.

13. The electronic component of claim 1, further comprising, within the area including the groove, a leading line electrically connected to the MEMS device, a via continuing upward the insulating layer, and an external terminal connected to the via.

14. The electronic component of claim 1, wherein the first and second cap layers have a polygonal shape in plan view, respectively, and the groove surrounding the cavity is provided selectively to correspond to each vertex of the polygonal shape.

15. An electronic component with a MEMS device, comprising:
a CMOS circuit disposed on a main surface side of a substrate;
an insulating layer disposed on the substrate to cover the CMOS circuit;
a MEMS device including a mechanically movable part, the MEMS device disposed on a part of the insulating layer;
a first cap layer disposed on the MEMS device and the insulating layer, the first cap layer forming a cavity to accommodate the MEMS device in conjunction with the insulating layer and having a plurality of through-holes thereon connecting with the cavity;
a sealing film disposed to seal the through-holes on the first cap layer;
a second cap layer disposed on the first cap layer to cover the sealing film, the second cap layer having a lower gas permeability than the first cap layer; and
an insulating protective film disposed on the second cap layer, the protective film having a greater flexibility than the second cap layer, wherein a ring-shaped groove is provided in a ring-shaped area surrounding the cavity from outside, and the ring-shaped groove is engraved on the upper surface of the second cap layer passing therethrough to a depth not passing through the insulating layer.

16. The electronic component of claim 15, wherein a metal film is embedded in the groove.

17. The electronic component of claim 15, wherein the groove is disposed along a dicing line used to separate the substrate into a plurality of chips.

18. The electronic component of claim 15, further comprising, within the ring-shaped area including the groove, an leading line electrically connected to the MEMS device and a via continuing downward the insulating layer.

19. The electronic component of claim 15, further comprising, within the ring-shaped area including the groove, an leading line electrically connected to the MEMS device, a via continuing upward the insulating layer, and an external terminal connected to the via.

20. A manufacturing method of an electronic component with a MEMS device, the method comprising:
forming an insulating layer on a substrate;
forming a MEMS device including a mechanically movable structure on a part of the insulating layer;
forming a sacrificial layer to cover the MEMS device;
forming a first cap layer on the sacrificial layer and the insulating layer;
forming a plurality of through-holes on the first cap layer;
removing the sacrificial layer through the through-holes on the first cap layer for forming a cavity therein, in which the movable part of the MEMS device moves freely;
forming a sealing film on a part of the first cap layer to seal the through-holes;
forming a second cap layer on the first cap layer to cover the sealing film; and
forming a groove in an area surrounding the cavity from outside, the groove engraved on the upper surface of the second cap layer passing therethrough to a depth not passing through the insulating layer.

21. An electronic component with a MEMS device, comprising:
an insulating layer on a substrate;
a MEMS device including a mechanically movable part, the MEMS device disposed on a part of the insulating layer;
a first cap layer disposed on the MEMS device and the insulating layer, the first cap layer forming a cavity to accommodate the MEMS device in conjunction with the insulating layer and having a plurality of through-holes thereon connecting with the cavity; and
a second cap layer disposed to cover the first cap layer, wherein
the first and second cap layers in a ring-shaped area surrounding the cavity from outside are formed such that at least the second cap layer has an end portion which inwardly extends farther than the end portions of the insulating film and the substrate.
